(19) United States
(12) Patent Application Publication
(10) Pub. No.: US 2020/0363462 A1
(43) Pub. Date: Nov. 19, 2020

(54) COMPUTER-IMPLEMENTED METHOD FOR RECONSTRUCTING THE TOPOLOGY OF A NETWORK OF CABLES

(71) Applicant: COMMISSARIAT A L'ENERGIE ATOMIQUE ET AUX ENERGIES ALTERNATIVES, PARIS (FR)

(72) Inventor: Geoffrey BECK, LE KREMLIN-BICETRE (FR)

(21) Appl. No.: 16/638,451

(22) PCT Filed: Aug. 8, 2018
(86) PCT No.: PCT/EP2018/071547

§ 371 Date: Feb. 11, 2020

(30) Foreign Application Priority Data
Aug. 17, 2017 (FR) 1757712

(51) Int. Cl. G01R 31/11; G01R 31/08; G01R 31/58

(52) U.S. Cl. CPC G01R 31/11; G01R 31/58; G01R 31/083; G01R 31/088

(57) ABSTRACT

A computer-implemented iterative method for reconstructing the topology of a cable network, includes the steps of: obtaining a measured time reflectogram, obtaining a simulated time reflectogram corresponding to a partial cable network comprising the singular points of the cable network reconstructed in the previous iterations and a matched load at the end of each cable, one endpoint of which is not yet reconstructed, subtracting the simulated time reflectogram from the measured time reflectogram in order to obtain a corrected time reflectogram, reconstructing the topology of the cable network by matching the peaks of the corrected reflectogram with the singular points of the cable network, the matching comprising searching, in the corrected reflectogram, for at least one second peak corresponding to a path of the signal comprising a main reflection off the ambiguous singular point and a secondary reflection off two junctions reconstructed in the previous iterations.

The invention relates to the field of the technical analysis and monitoring of complex cable networks. More precisely, it pertains to a method for reconstructing the topology of a cable network. The invention aims to propose a method for determining the topology of a network, that is to say the interconnection points between a plurality of cables, the number of cables connected at each point, but also the loads at the end of the cable. The proposed method is based on the use of a time reflectogram obtained by injecting a controlled signal into the cable network and then by measuring the signal reflected off the various impedance discontinuities of the network. The invention thus relates more generally to the field of what are called reflectometry methods, which aims to provide information about a cable or a cable network from a reflectogram.

Cables are ubiquitous in all electrical systems, for supplying power or transmitting information within buildings or vehicles such as aircraft. These cables are subjected to the same constraints as the systems that they link, and may be subject to failures. It is therefore necessary to be able to analyze their state and to provide information about the detection of faults, but also their location and their type, so as to assist with maintenance. Conventional reflectometry methods enable this type of test.

Reflectometry methods use a principle close to that of radar: an electrical signal, the probe signal or reference signal, which is more often than not high-frequency or wideband, is injected at one or more locations of the cable to be tested. The signal propagates in the cable or the network and returns a portion of its power when it encounters a singularity that causes an impedance discontinuity. An impedance discontinuity may be caused for example by a connection, by the end of the cable or by a fault or more generally by a change in the propagation conditions for the signal in the cable. It is caused by a fault that locally modifies the characteristic impedance of the cable by bringing about a change in its linear parameters.

Analyzing the signals returned to the injection point makes it possible to deduce therefrom information about the presence and the location of these discontinuities, and therefore possible faults. An analysis in the time or frequency domain is usually performed. These methods are denoted using the acronyms TDR, stemming from the expression “time domain reflectometry”, and FDR, stemming from the expression “frequency domain reflectometry”.

The invention applies to any type of cable network, notably electric cables, in particular power transmission cables or communication cables, in fixed or mobile installations. The cables in question may be coaxial, bifilar, in parallel rows, in twisted pairs or in another arrangement, provided that it is possible to inject a reflectometry signal into them at a point of the cable network and to measure its reflection at the same point or at another point.

The aim of the present invention is notably to make it possible to reconstruct the topology of complex cable networks whose layouts are not available or for which urgent intervention requires immediate knowledge of the topology of the network. This type of problem exists notably for electric or power cable networks within a building or within a vehicle. An engineer wishing to repair the network following the detection of an electrical problem may need precise knowledge of the topology of the network in order to help him to establish his diagnosis. Moreover, some buildings have a level of confidentiality which, by nature, prohibits the dissemination of the layouts of the electrical network.

Another problem is specific to the field of reflectometry methods applied to the detection of faults.

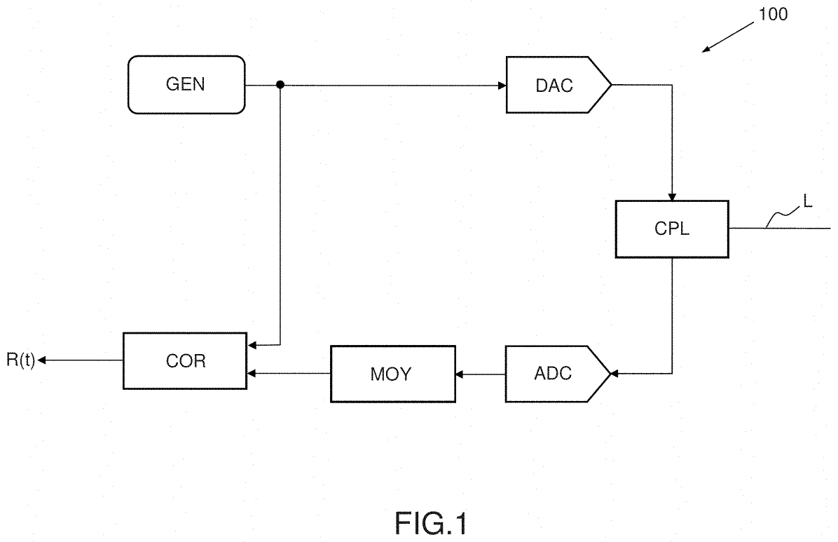

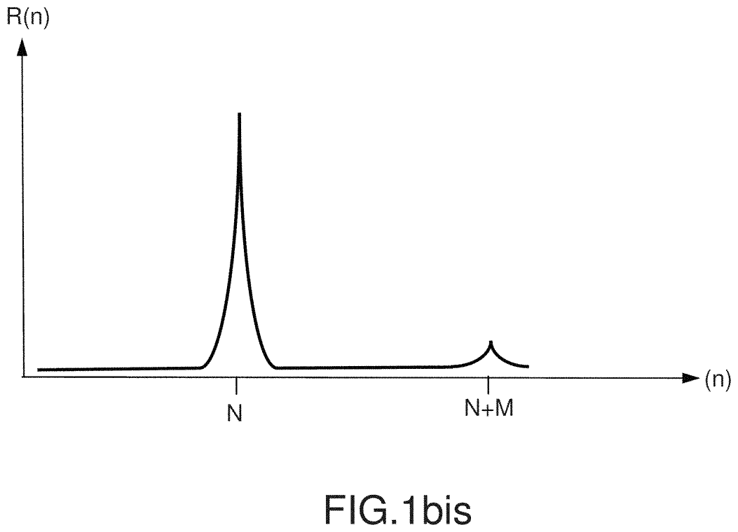

FIG. 1 shows a diagram of a system 100 for analyzing a fault in a transmission line L, such as a cable, using a conventional time reflectometry method from the prior art. Such a system primarily comprises a generator GEN for generating a reference signal. The digital reference signal that is generated is converted into analog via a digital-to-analog converter DAC and is then injected at a point of the transmission line L by way of a directional coupler CPL or any other device for injecting a signal into a line. The signal propagates along the line and reflects off the singularities that it comprises. In the absence of a fault on the line, the signal reflects off the end of the line if the termination of the line is not matched. In the presence of a fault on the line, the signal partially reflects off the impedance variation caused by the fault. The reflected signal is propagated back to a measurement point, which may be the same as the injection point or different. The back-propagated signal is measured via the directional coupler CPL and then converted into digital by an analog-to-digital converter ADC. A correlation COR is then made between the measured digital signal and a copy of the digital signal generated prior to injection in order to produce a time reflectogram R(t) corresponding to the intercorrelation between the two signals.

As is known in the field of time reflectometry-based diagnostic methods, the position d_{DF} of a fault on the cable L, in other words its distance to the injection point of the signal, is able to be obtained directly based on the measurement, on the calculated time reflectogram R(t), of the duration t_{DF} between the first amplitude peak shown on the reflectogram and the amplitude peak corresponding to the signature of the fault.

FIG. 1bis shows an example of a reflectogram R(n) obtained using the system from FIG. 1, in which a first amplitude peak is observed on an abscissa N and a second amplitude peak is observed on an abscissa N+M. The first amplitude peak corresponds to the reflection of the signal at the injection point into the cable, while the second peak corresponds to the reflection of the signal off an impedance discontinuity caused by a fault.

Various known methods may be contemplated to determine the position d_{DF}. A first method consists in applying the relationship linking distance and time: d_{DF}=V_{g}·t_{DF}/2 where V_{g} is the propagation speed of the signal in the cable. Another possible method consists in applying a proportionality relationship of the type d_{DF}/t_{DF}=L_{c}/t₀, where L_{c} is the length of the cable and t₀ is the duration, measured on the reflectogram, between the amplitude peak corresponding to the impedance discontinuity at the injection point and the amplitude peak corresponding to the reflection of the signal off the endpoint of the cable.

An analysis device (not shown in FIG. 1) is responsible for analyzing the reflectogram R(t) in order to deduce therefrom information about the presence and/or location of faults, as well as the possible electrical characteristics of the faults. In particular, the amplitude of a peak in the reflectogram is linked directly to the reflection coefficient of the signal off the impedance discontinuity caused by the fault.

Detecting and locating faults by way of a reflectometry system is of great benefit because the earlier a fault is detected, the more it is possible to intervene in order to correct/repair the fault before the damage is too great. Thus, monitoring the state of health of a cable makes it possible to maintain reliable use of the cable throughout its entire service life.

In the case of a complex cable network comprising numerous interconnections, analyzing a reflectogram in order to characterize the presence of faults is more difficult to implement since the junctions between the various cables of the network as well as the loads at the end of the cables also cause signal reflections that may be superimposed on those resulting from a fault. In particular, multiple reflections may exist between a plurality of junctions or more generally a plurality of singular points of the network. A singular point is typically either a junction or a load at the endpoint of a cable, or more generally any element bringing about a break in impedance at a point of a cable. The superimpositions of multiple reflections of the signal at various singular points of the network may cancel each other out, amplify one another or combine so as to create numerous stray peaks in the reflectogram. Furthermore, the number of signal reflections tends to increase exponentially with the number of cables interconnected in the network. Thus, complex cable networks produce reflectograms that are very complex to analyze.

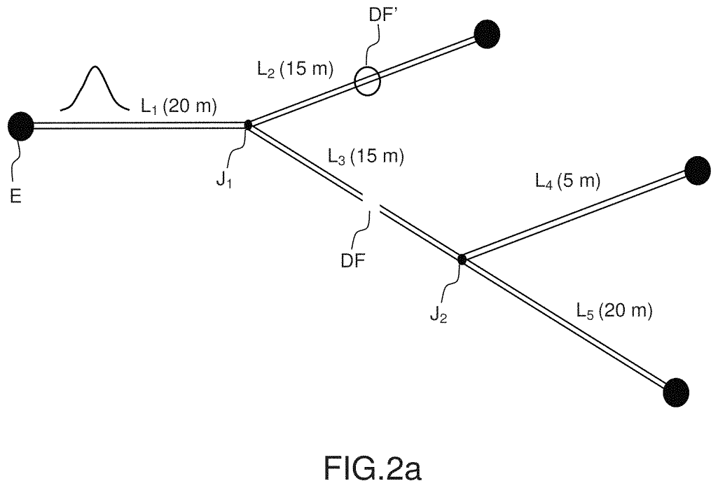

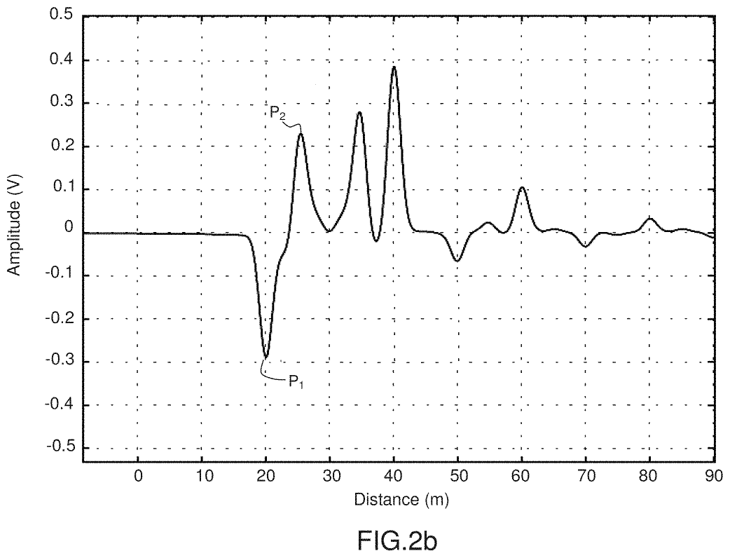

In particular, even if a peak characteristic of a fault is able to be identified in a reflectogram, the location of the fault may be ambiguous because the reflectogram makes it possible only to ascertain the distance between the fault and the injection point of the signal, but not the branch of the network on which the fault is situated. To illustrate this phenomenon, an exemplary cable network comprising five branches and two junctions is shown in FIG. 2a. The reflectogram associated with this network is illustrated in FIG. 2b, considering the injection and the measurement of the signal at the point E of the network. In the reflectogram, a first peak P1 of negative amplitude that corresponds to the first junction J1 is identified, and then a second peak P2 that corresponds to a fault DF. It is not possible to precisely locate this fault DF because it may be located either on the branch L2 at the point DF′ or on the branch L3 at the point DF. The other peaks of the reflectogram correspond to direct or multiple reflections off the endpoints of the various cables and off the second junction J2.

It is therefore seen that the methods for monitoring the state of health of a cable network by way of reflectometry are not sufficient when the cable network is complex, that is to say when it has many branches and interconnections.

There is therefore a need for a method for determining the topology of a cable network without a priori information. Knowledge of the topology of the network may be combined with a conventional reflectometry method in order to be able to better use a reflectogram in order to identify and locate possible faults. Specifically, if the singular points of the network, that is to say the junctions between cables and the lengths of the various branches of the network, are known, it is possible to match certain peaks of a reflectogram to these singular points and thus discriminate between the peaks that correspond to physical elements of the network and those that correspond to faults.

American patent application US20060182269 describes a method for reconstructing the topology of a cable network by using a reflectogram.

The described method is limited to the case of networks in which all of the cables are terminated by an open circuit or a short circuit. These hypotheses are not realistic because, in a real case, apparatuses may be connected to the endpoint of the cables with a load that is not matched to the cable.

Furthermore, this method involves, at each iteration, simulating reflectograms associated with a plurality of network topology hypotheses deduced from the identification of a peak in the measured reflectogram. For very complex networks, the number of hypotheses to be simulated may be very high, and the step of removing the ambiguities between all of the hypotheses may include a very large number of necessary calculations. Moreover, the criterion used to remove the ambiguities between various network topology hypotheses is based on a global error calculation between a measured reflectogram and a simulated reflectogram. This criterion does not make it possible to correctly discriminate between the amplitude peaks associated with single reflections or with multiple reflections of the signal off the impedance discontinuities of the cables of the network. Thus, using such a criterion may lead to the retention of topology hypotheses that, although they have a simulated reflectogram close to the reflectogram measured on the real network, differ greatly from the topology of the real network.

The invention aims to solve the drawbacks from the prior art by proposing a method for reconstructing the topology of a cable network, which method finely takes into account the influence of multiple reflections of the signal off the singular points of the network in order to improve the removal of ambiguity between various network topology hypotheses having similar reflectograms.

One subject of the invention is a computer-implemented iterative method for reconstructing the topology of a cable network, comprising the steps of:
Obtaining a measured time reflectogram from a signal previously injected into the cable network, the reflectogram comprising a plurality of amplitude peaks,
Obtaining a simulated time reflectogram corresponding to a partial cable network comprising the singular points of said cable network reconstructed in the previous iterations and a matched load at the end of each cable, one endpoint of which is not yet reconstructed,
Subtracting the simulated time reflectogram from the measured time reflectogram in order to obtain a corrected time reflectogram,
Reconstructing the topology of the cable network by matching the peaks of the corrected reflectogram with the singular points of the cable network,
The matching comprising at least one search to remove ambiguity between at least two different topologies comprising an ambiguous singular point corresponding to one and the same first peak,
The search to remove ambiguity comprising searching, in the corrected reflectogram, for at least one second peak corresponding to a path of the signal comprising a main reflection off said ambiguous singular point and a secondary reflection off two junctions reconstructed in the previous iterations.

According to one particular aspect of the invention, the search for at least one second peak is iterative, the two junctions taken from among the junctions reconstructed in the previous iterations being taken to be equal respectively to a first junction and a second junction reconstructed after the first junction, at each new iteration the second junction being taken to be equal to the following junction on the path connecting the first junction to said ambiguous singular point, the ambiguous singular point being located after the second junction in the last iteration for which a second peak was found.

According to one particular aspect of the invention, said first junction is the first reconstructed junction of the network.

According to one particular aspect of the invention, the at least one second peak is sought, in the corrected reflectogram, on a time abscissa determined from the time abscissa of said first peak and from the length between the two junctions taken from among the junctions reconstructed in the previous iterations.

According to one particular variant, the method according to the invention comprises directly reconstructing the first singular point of the cable network from an evaluation of the sign and of the abscissa of the first peak of the measured time reflectogram.

According to one particular variant, the method according to the invention comprises evaluating the sign of a peak of the corrected time reflectogram in order to determine whether the singular point corresponding to the peak is a junction between two cables or a load at the end of the cable.

According to one particular variant, the method according to the invention comprises determining the number of cables connected at a junction from the evaluation of the amplitude of a peak of the corrected time reflectogram, corresponding to the junction.

According to one particular variant, the method according to the invention comprises determining the length of a cable connecting two singular points reconstructed from the abscissas of two peaks, in the corrected time reflectogram, corresponding to the two reconstructed singular points.

According to one particular variant, the method according to the invention comprises determining the value of a load at the end of the cable from the amplitude of a peak of the corrected time reflectogram, corresponding to the load.

According to one particular variant, the time reflectogram is obtained from measuring the signal reflected off at least one singular point of the network and propagated back to a measurement point.

According to one particular variant, the method according to the invention comprises a stop test for stopping the reconstruction, comprising:
calculating an error criterion between the measured time reflectogram and the
simulated time reflectogram and
comparing the error criterion with a stop threshold.

According to one particular variant, the error criterion is equal to the error between the measured time reflectogram and the simulated time reflectogram, weighted so as to assign a temporally decreasing weight to the peaks of the reflectograms.

According to one particular variant, the method according to the invention comprises a step of displaying the reconstructed topology of the cable network on a display device.

According to one particular variant, the method according to the invention comprises a preliminary step of injecting the signal into the cable network.

Another subject of the invention is a computer program comprising instructions for executing the method for reconstructing the topology of a cable network according to the invention when the program is executed by a processor.

Another subject of the invention is a recording medium able to be read by a processor and on which there is recorded a program comprising instructions for executing the method for reconstructing the topology of a cable network according to the invention when the program is executed by a processor.

Other features and advantages of the present invention will become more clearly apparent upon reading the following description with reference to the appended drawings, in which:

FIG. 1 shows a diagram of a reflectometry system according to the prior art,

FIG. 1bis shows an example of a reflectogram obtained with the reflectometry system of FIG. 1,

FIGS. 2a and 2b respectively show an example of a cable network and its associated reflectogram,

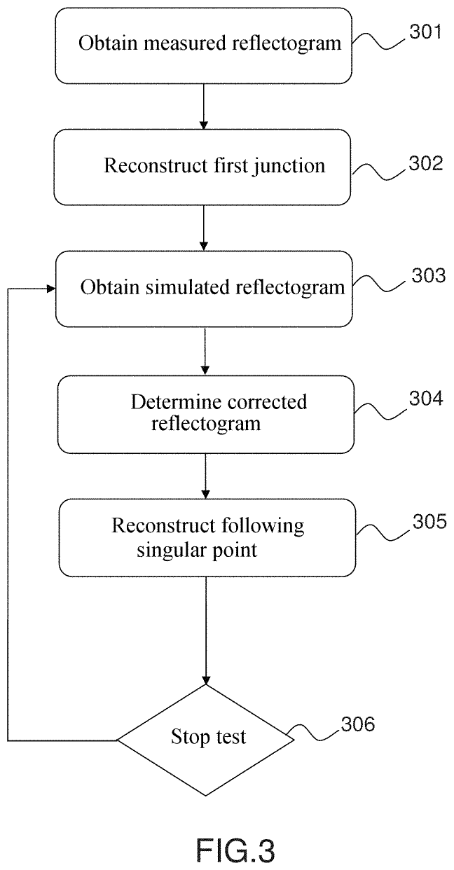

FIG. 3 shows a flowchart describing the steps for implementing a method for reconstructing the topology of a network, according to one embodiment of the invention,

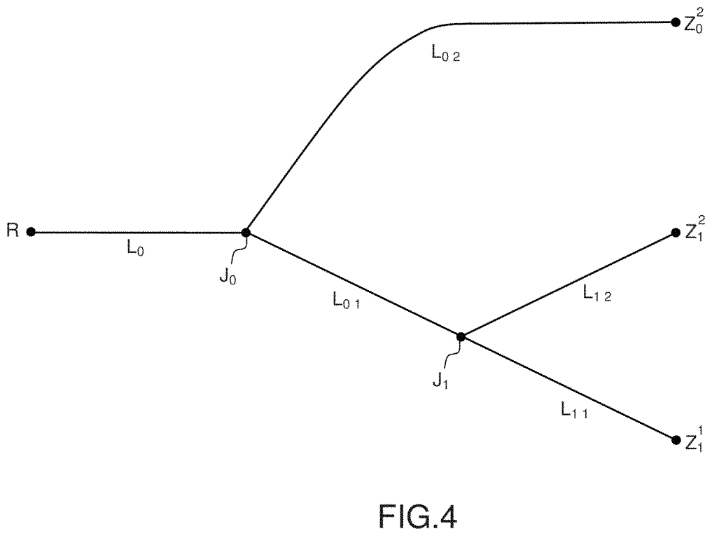

FIG. 4 shows an example of a cable network to which the invention is applied,

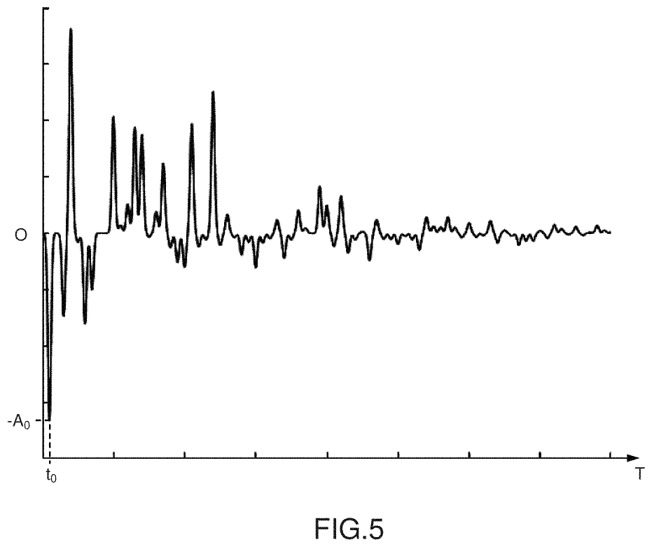

FIG. 5 shows a time reflectogram associated with the cable network of FIG. 4,

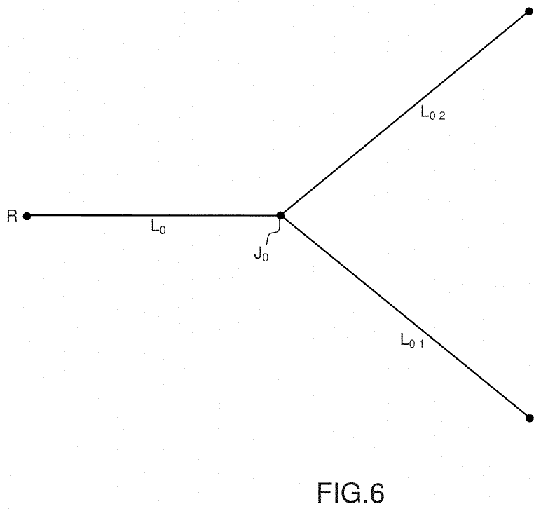

FIGS. 6-14 show several figures illustrating the stages for implementing the invention for the exemplary network of FIG. 4.

The invention aims to determine the following parameters of the topology of a cable network: the number of junctions of the network, the number of branches connected to each junction, the length of each branch as well as the impedance of the loads at the endpoint of each branch. The networks under consideration are formed by homogeneous cables of the same type, that is to say all having the same characteristic impedance. The loads at the endpoints of the network are resistive and have impedances greater than the characteristic impedance of the cables.

FIG. 3 details the steps for implementing a method according to one embodiment of the invention. By way of non-limiting illustration, the description of the method is given for a particular exemplary cable network described in FIG. 4. The network described in FIG. 4 comprises two junctions J₀,J₁, three output loads Z₀², Z₁², Z₁¹ and five branches L₀, L_{0 1}, L_{0 2}, L_{1 1}, L_{1 2} of different lengths. FIG. 5 shows a reflectogram obtained for the network of FIG. 4 by injecting a signal at the root point R and by measuring the back-propagated signal at this same point R.

The invention may be applied generally to any type of cable network able to be represented by a graph, apart from networks forming loops.

In a first step 301 of the method, a time reflectogram Rₘ is obtained from a reflectometry measurement. As indicated in the preamble, a reflectometry measurement is obtained by injecting a controlled signal at a point of the cable network and then by measuring, at the same point or at a different point of the network, the signal that is propagated back after having undergone multiple reflections off the impedance discontinuities that the network contains. The reflectometry measurement may be obtained by way of the device described in FIG. 1 or any other equivalent apparatus for performing the same function. The signal that is used may be of varying nature: it may be a simple Gaussian signal, a time slot or a pulse or else a more complex signal insofar as the shape of the signal is bell-shaped, for example the shape of a Gaussian curve or a Lorentz curve. Depending on the exact nature of the signal, the time reflectogram Rₘ is obtained directly by measuring the back-propagated signal, or else by an intercorrelation calculation between this measurement and a copy of the signal injected into the network. In general, any signal measurement containing the information relating to the reflections of the signal off the singular points of the network, that is to say the junctions and the loads at the end of cables, is compatible with the invention. It should be noted that measuring the time reflectogram Rₘ requires access to only one test port of the network.

The time reflectogram Rₘ is then analyzed in order to identify peaks of positive or negative amplitude and to associate each of them with a singular point of the network to be reconstructed.

The sign of a peak makes it possible to determine whether the associated signal has reflected off a load at the end of the cable or off a junction. If the sign is negative, it is a junction, and if the sign is positive, it is a load at the end of the cable.

In a preliminary step 302, the first singular point of the cable network is reconstructed directly from analyzing the first peak of the reflectogram.

The first peak identified in the reflectogram necessarily corresponds to a junction, in the case of a cable network comprising more than one cable. The sign of the first peak is therefore normally negative. By noting the time abscissa t₀ of the peak in the reflectogram of FIG. 5, the distance between the measurement point R of the signal and the first junction J₀ is deduced therefrom: L₀=vt_{0/}2, where v is the propagation speed of the signal in the cable. The value A₀ of the amplitude of the peak makes it possible to deduce the number of branches connected to the first junction J₀, also called order of the junction or order of the node. The number of branches m connected to a node may be determined using the following relationship:
m₀=E[2/(A₀+1)], where E[ ] is the excess integer part function and A₀ is the absolute value of the amplitude of the peak.

In the case of the example given in FIGS. 4 and 5, the number of branches connected to the first junction is m₀=3.

The following steps 303-307 of the method are executed iteratively.

At each iteration, consideration is given to the network as reconstructed in the previous iteration. In step 303, a reflectogram associated with the network reconstructed in the previous iteration is determined by simulation, by simulating matched loads at the endpoints of the branches of the network that are not yet provided with already identified endpoints.

For this purpose, consideration is given to the same signal as that used to obtain the measured reflectogram Rₘ and the same conditions for injecting the signal and measuring the back-propagated signal. The back-propagated signal is simulated for example by applying a numerical model of the propagation of the signal through the cables of the simulated network. In particular, this model takes into account the reflection coefficients and the transmission coefficients at each junction or each load that the simulated network contains. A person skilled in the art may use his general knowledge of wave propagation to determine a simulated reflectogram, in particular based on the telegrapher's equations, which make it possible to describe the evolution of the voltage and of the current on an electricity line as a function of distance and time.

$$\begin{matrix}\frac{\partial v ( x , t )}{\partial x} = - Ri ( x , t ) - L \frac{\partial i ( x , t )}{\partial t} & ( 1 ) \\ \frac{\partial i ( x , t )}{\partial x} = - G v ( x , t ) - C \frac{\partial v ( x , t )}{\partial t} & ( 2 )\end{matrix}$$

The parameters R, L, C, G correspond respectively to the resistance, to the inductance, to the capacitance and to the conductance of the line.

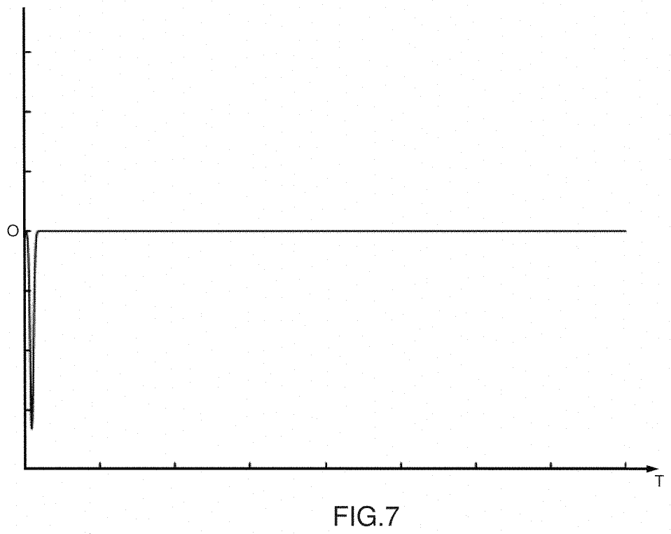

Returning to the example of FIG. 4, step 303 consists in simulating the network shown in FIG. 6 and its associated reflectogram illustrated in FIG. 7.

FIG. 6 shows the network as reconstructed in the first step 302 of the method, that is to say with a first junction J₀ and three cables connected to this junction, including the cable that connects the junction J₀ to the root point R. The simulated network of FIG. 6 comprises loads matched to the endpoints of the two other branches connected to the junction J₀. For such a network, the signal injected at the point R is partially reflected off the junction J₀ and partially transmitted to the two branches connected to the junction J₀. In the presence of matched loads, the signal does not undergo any reflection off the endpoints of the two branches. As a result, the reflectogram measured at the point R and illustrated in FIG. 7 contains only the first peak already identified in step 302.

In a following step 304, the reflectogram simulated in step 303 is subtracted from the reflectogram measured in step 301 in order to obtain a corrected reflectogram in which the peaks associated with reflections off the already reconstructed singular points are eliminated.

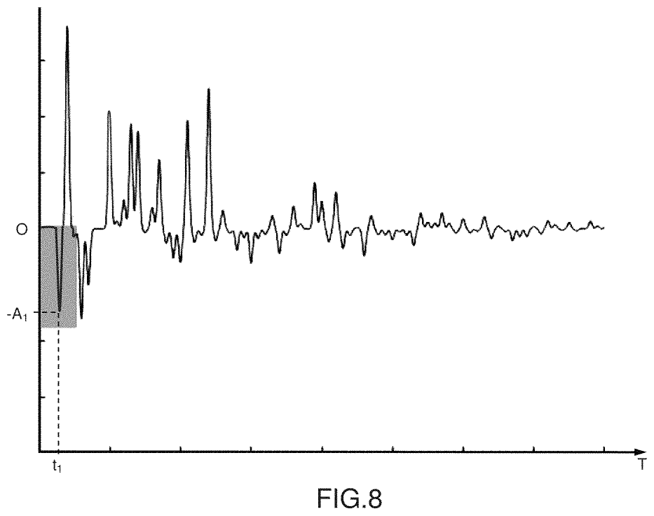

The corrected reflectogram is shown in FIG. 8. It is obtained by subtracting the reflectogram of FIG. 7 from that of FIG. 5.

The corrected reflectogram obtained in step 304 no longer contains peaks associated with single or multiple reflections of the signal off the singular points of the network already reconstructed in the previous iterations. It thus contains only peaks associated with reflections of the signal off the singular points (loads or junctions) that have not yet been identified. By carrying out this operation, this makes it possible to reconstruct the singular points of the network as the method is iterated by matching the peaks of the corrected reflectogram and the junctions or the loads of the network.

The first peak that has not yet been analyzed in the previous iterations is then sought in the corrected reflectogram. Step 305 of the method consists in reconstructing the singular point of the network that is at the origin of a reflection of the signal that generated the identified peak.

Step 305 of the method is first of all explained in a general context of any network, and then an application of this step to the particular example described in FIGS. 4 to 8 is then introduced.

The first peak of the corrected reflectogram that has not already been identified beforehand is identified, and its amplitude Aₙ and its time abscissa tₙ on the reflectogram are evaluated. If the sign of the peak is negative, then it is known that it corresponds to a reflection of the signal off a junction. By contrast, if the sign of the peak is positive, it is known that it corresponds to a reflection of the signal off a load at the end of the cable. The time abscissa tₙ of the peak makes it possible to determine the distance between the root point R of the network and the junction or the load. From the amplitude, it is also possible to determine the number of branches connected to the point (if it is a junction) or the value of the load at the end of the cable (if it is a load).

However, if the network partially reconstructed in the previous iteration already has one or more junctions to which several branches are connected, simply analyzing the time abscissa tₙ does not make it possible to identify the branch on which the corresponding singular point (junction or load) is situated. Moreover, the identified peak may correspond to a single reflection of the signal off the singular point or to a multiple reflection of the signal off several singular points that have not yet been reconstructed.

In order to precisely locate the singular point, step 305 comprises searching to remove ambiguity regarding the precise location of the singular point. This removal of ambiguity consists in searching, in the reflectogram, for the presence of at least one other peak that corresponds to a path of the signal comprising a main reflection off the sought singular point and a secondary reflection off two previously reconstructed junctions. The additional peak is sought on the abscissa tₙ+2l_{p,q}/v, where l_{p,q} is the length of the cable connecting an already reconstructed first junction p to an already reconstructed second junction q, situated after the first junction p. In practice, the first junction p is chosen, then the second junction q is varied among all of the junctions situated after the first chosen junction p, in order from closest to furthest away. If a peak is found on the abscissa tₙ+2l_{p,q}/v, then this means that the sought singular point is located after the junction q, on one of the branches that has not yet been completely reconstructed. Advantageously, the first junction p is taken to be equal to the first junction of the network, reconstructed in step 302. The reason for this choice is that the reflections of the signal off the first junction of the network have a higher amplitude than the reflections off junctions further away from the root point R. The peak situated on the abscissa tₙ+2l_{p,q}/v corresponds to a path of the signal that passes through the following path R-p,p-q,q-p,p-T,T-R, where T is the sought singular point.

The application of step 305 to the reflectogram of FIG. 8 is now illustrated. This reflectogram is the one obtained in step 304 of the first iteration of the method. The first peak of the reflectogram is identified by its amplitude A₁ and its time abscissa t₁. The peak is negative, which means that the associated singular point is a junction. Its distance to the root point and then the length l₁ of the cable L_{0 1} are determined, thereby making it possible to reconstruct the junction J₁ on the network of FIG. 4. The number of branches connected to this junction is also determined, from the absolute value of the amplitude of the peak. This number is equal to three, which means that two additional branches branch off from the junction J₁.

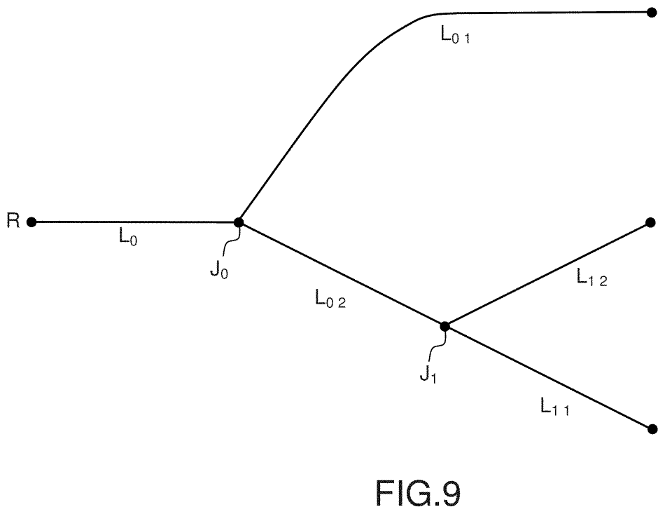

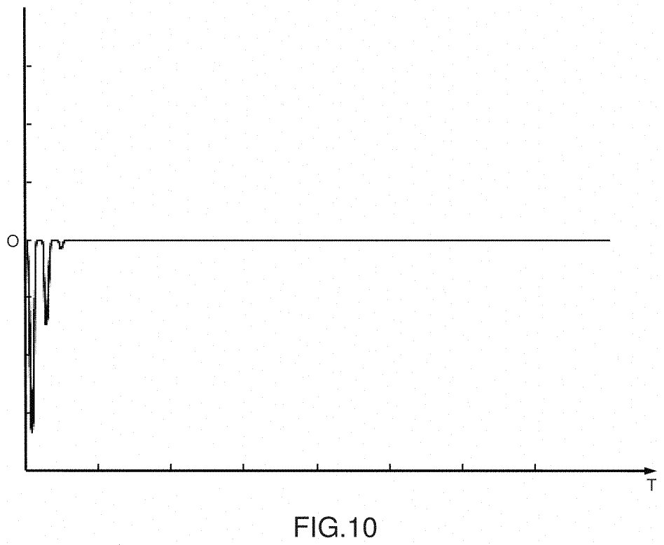

We then move to the following iteration, reiterating step 303 which consists in simulating a reflectogram obtained on a partially reconstructed network in the current iteration and shown in FIG. 9. In this network, the endpoints of the branches L_{0 1}, L_{1 1} and L_{1 2} are not reconstructed, and they are replaced with matched loads. The simulated reflectogram corresponding to the network of FIG. 9 is shown schematically in FIG. 10.

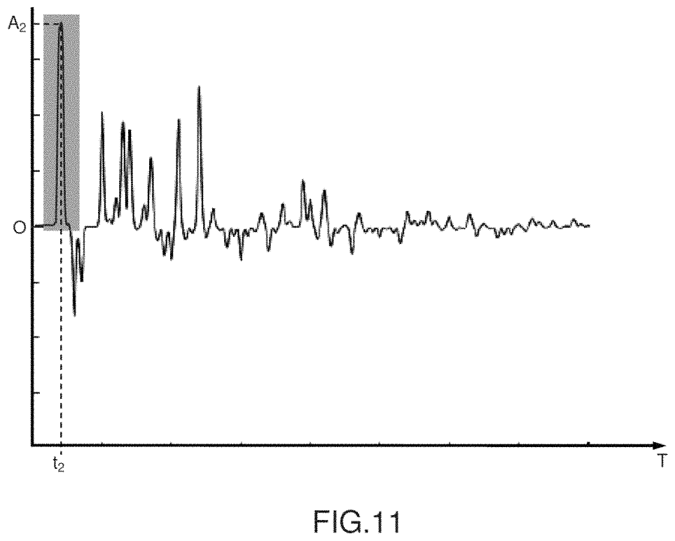

FIG. 11 shows the reflectogram corrected at the end of step 304 by subtracting the simulated reflectogram of FIG. 10 from the initially measured reflectogram.

Step 305 is then applied to the reflectogram of FIG. 11 by searching for the first peak of this reflectogram and by noting its coordinates (A₂,t₂). This peak is positive, which means that it corresponds to a load. Now, this load may be located at the endpoint of any of three branches that have not yet been reconstructed. In order to be able to locate the load precisely, it is sought whether there is a peak around the abscissa t₂+2l₁/v. In this example, no peak is located on this abscissa, and it is therefore deduced therefrom that the load is located after the first junction J₀ and not after the second junction J₁. From the coordinates (A₂,t₂) of the peak, the length of the cable L_{0 2} and the value of the load Z₀² are deduced therefrom.

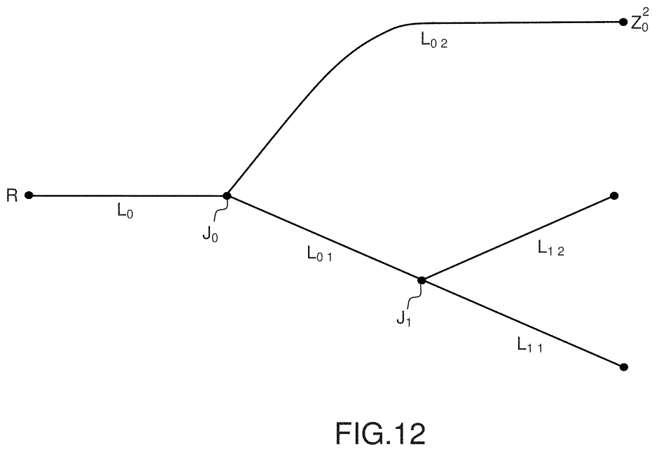

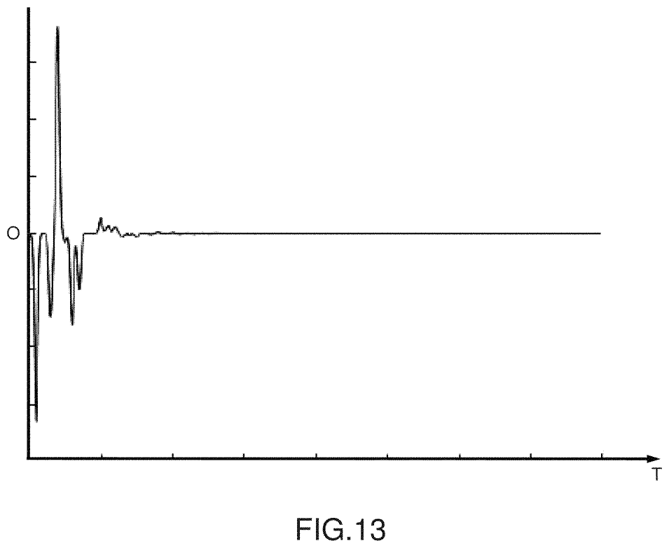

We then move to the 3rd iteration of the method by simulating the partially reconstructed network shown in FIG. 12 in which only the two branches L_{1 1} and L_{1 2} connected to the second junction J₁ are not reconstructed. Matched loads at the endpoints of these two branches are simulated in order to obtain the simulated reflectogram of FIG. 13.

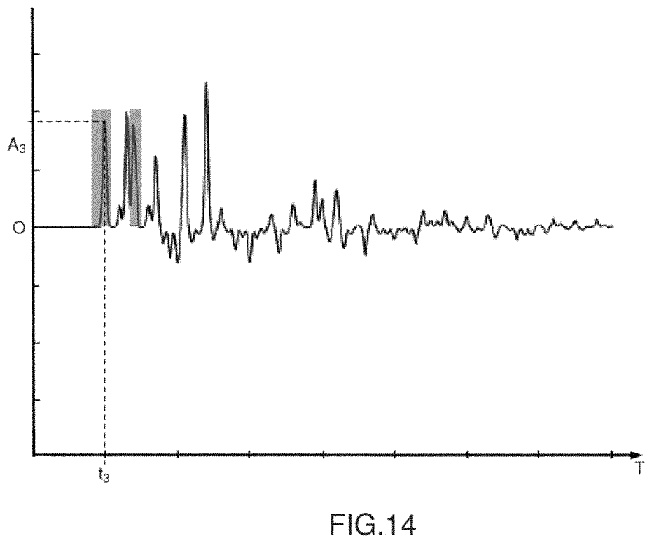

The corrected reflectogram of FIG. 14 is then obtained by subtracting the reflectogram of FIG. 13 from the initially measured reflectogram.

The first peak of this new corrected reflectogram is identified by noting its coordinates (A₃,t₃). This peak is positive, which means that there is a load at the endpoint of one of the two branches L_{1 1} and L_{1 2} connected to the second junction J₁. A peak is effectively present on the abscissa t₃+2l₁/v, thereby effectively confirming the presence of a load after the second junction J₁. From the coordinates (A₃,t₃) of the peak, the length of the cable L_{1 1} and the value of the load Z₁¹ are deduced therefrom.

Steps 303-305 of the method are reiterated one last time once again in order to characterize the last load Z₁² situated at the endpoint of the last non-reconstructed branch L_{1 2}.

In each iteration of the method, the number m of branches connected to a junction may be determined from the following relationship:

$$Γ = \frac{2}{m} - 1 ,$$

where Γ is the reflection coefficient of a junction.

Likewise, the impedance of a load Zₗ may be determined from the following relationship:

$$Γ = \frac{{Z}_{l} - {Z}_{c}}{{Z}_{l} + {Z}_{c}}$$

where Z_{c} is the characteristic impedance of the cables of the network.

The reflection coefficient off a junction or a load is linked directly to the amplitude of a peak measured in a reflectogram. Thus, from the value of the amplitude Aₙ of a peak, it is possible to determine the values of m or Zₗ using mathematical relationships well known to those skilled in the art.

Precisely, in iteration n, if a junction is identified, the number of branches connected to this junction is given by the relationship:

$$m = \frac{2}{{( \frac{{m}_{0}}{2} )}^{2} {A}_{n} + 1}$$

where m₀ is the order of the first junction, equal to the number of branches connected to the first junction.

Likewise, if a load is identified, the value of this load is given by the relationship:

$${Z}_{l} = {Z}_{c} ( \frac{1 + {Γ}_{n}}{1 - {Γ}_{n}} ) , where {Γ}_{n} = {A}_{n} \cdot {( \frac{{m}_{0}}{2} )}^{2} \cdot {( \frac{{m}_{1}}{2} \cdot \frac{{m}_{2}}{2} … \frac{{m}_{n - 1}}{2} )}^{2}$$

Where mᵢ is the order of the i^{th} reconstructed junction on the path connecting the root point R to the load, i varying from 1 to n-1.

The method according to the invention is stopped when the entire network is reconstructed.

In one particular variant embodiment, a stop test 306 is implemented in order to stop the method when the partially reconstructed network is close enough to the real network. This variant has an advantage notably when the loads at the endpoints of the network are too close to the characteristic impedance of the cables or if the number of cables in the network is very large. In such a scenario, the reflections of the signal may have amplitudes of a level too low to be detected in a reflectogram.

In this case, the stop test consists in calculating a proximity criterion between the initially measured reflectogram R(t) and the simulated reflectogram Rⁿ(t) at the end of step 303 of the nth iteration of the method, and then in comparing this proximity criterion to a stop threshold Crit. The method is stopped when the proximity criterion is lower than the stop threshold. Advantageously, the proximity criterion may be weighted so as to give a decreasing weight to the peaks, so as to give priority to the first peaks of the reflectogram that have greater reliability. The stop test may for example be implemented using the following relationship:

$${\int }_{ℝ +} {\vert R ( t ) - {R}^{n} ( t ) \vert}^{2} \frac{d t}{1 + {t}^{2}} \leq Crit .$$

The method according to the invention may be implemented as a computer program, the method being applied to a reflectometry measurement Rₘ previously acquired using a conventional reflectometry device. The invention may be implemented as a computer program comprising instructions for the execution thereof. The computer program may be recorded on a recording medium that is able to be read by a processor. The reference to a computer program that, when it is executed, performs any one of the previously described functions is not limited to an application program running on a single host computer. On the contrary, the terms computer program and software are used here in a general sense to refer to any type of computer code (for example, application software, firmware, microcode, or any other form of computer instruction) that may be used to program one or more processors so as to implement aspects of the techniques described here. The computing means or resources may notably be distributed (“cloud computing”), possibly using peer-to-peer technologies. The software code may be executed on any suitable processor (for example a microprocessor) or processor core or a set of processors, whether they are provided in a single computing device or distributed between several computing devices (for example such as possibly accessible in the environment of the device). The executable code of each program allowing the programmable device to implement the processes according to the invention may be stored for example in the hard disk or in read-only memory. Generally speaking, the program or programs may be loaded into one of the storage means of the device before being executed. The central unit is able to command and direct the execution of the instructions or software code portions of the program or programs according to the invention, which instructions are stored in the hard disk or in the read-only memory or else in the other abovementioned storage elements.

As an alternative, the invention may also be implemented in an onboard device of the type in FIG. 1 furthermore comprising a computer configured so as to execute the method according to the invention in order to provide one or more probable topologies of the network under test from a measured reflectogram Rₘ. The device may also comprise a means for displaying the results of the method in the form of a graph or in numerical form.

1. A computer-implemented iterative method for reconstructing the topology of a cable network, comprising the steps of:
obtaining a measured time reflectogram from a signal previously injected into the cable network, the reflectogram comprising a plurality of amplitude peaks,
obtaining a simulated time reflectogram corresponding to a partial cable network comprising the singular points of said cable network reconstructed in the previous iterations and a matched load at the end of each cable, one endpoint of which is not yet reconstructed,
subtracting the simulated time reflectogram from the measured time reflectogram in order to obtain a corrected time reflectogram,
reconstructing the topology of the cable network by matching the peaks of the corrected reflectogram with the singular points of the cable network,
the matching comprising at least one search to remove ambiguity between at least two different topologies comprising an ambiguous singular point corresponding to one and the same first peak,
the search to remove ambiguity comprising searching, in the corrected reflectogram, for at least one second peak corresponding to a path of the signal comprising a main reflection off said ambiguous singular point and a secondary reflection off two junctions reconstructed in the previous iterations.

2. The method for reconstructing the topology of a cable network as claimed in claim 1, wherein the search for at least one second peak is iterative, the two junctions taken from among the junctions reconstructed in the previous iterations being taken to be equal respectively to a first junction and a second junction reconstructed after the first junction, at each new iteration the second junction being taken to be equal to the following junction on the path connecting the first junction to said ambiguous singular point, the ambiguous singular point being located after the second junction in the last iteration for which a second peak was found.

3. The method for reconstructing the topology of a cable network as claimed in claim 2, wherein said first junction is the first reconstructed junction of the network.

4. The method for reconstructing the topology of a cable network as claimed in claim 1, wherein the at least one second peak is sought, in the corrected reflectogram, on a time abscissa determined from the time abscissa of said first peak and from the length between the two junctions taken from among the junctions reconstructed in the previous iterations.

5. The method for reconstructing the topology of a cable network as claimed in claim 1, comprising directly reconstructing the first singular point of the cable network from an evaluation of the sign and of the abscissa of the first peak of the measured time reflectogram.

6. The method for reconstructing the topology of a cable network as claimed in claim 1, comprising evaluating the sign of a peak of the corrected time reflectogram in order to determine whether the singular point corresponding to the peak is a junction between two cables or a load at the end of the cable.

7. The method for reconstructing the topology of a cable network as claimed in claim 1, comprising determining the number of cables connected at a junction from the evaluation of the amplitude of a peak of the corrected time reflectogram, corresponding to the junction.

8. The method for reconstructing the topology of a cable network as claimed in claim 1, comprising determining the length of a cable connecting two singular points reconstructed from the abscissas of two peaks, in the corrected time reflectogram, corresponding to the two reconstructed singular points.

9. The method for reconstructing the topology of a cable network as claimed in claim 1, comprising determining the value of a load at the end of the cable from the amplitude of a peak of the corrected time reflectogram, corresponding to the load.

10. The method for reconstructing the topology of a cable network as claimed in claim 1, wherein the time reflectogram is obtained from measuring the signal reflected off at least one singular point of the network and propagated back to a measurement point.

11. The method for reconstructing the topology of a cable network as claimed in claim 1, comprising a stop test for stopping the reconstruction, comprising:
calculating an error criterion between the measured time reflectogram and the simulated time reflectogram and
comparing the error criterion with a stop threshold.

12. The method for reconstructing the topology of a cable network as claimed in claim 1, wherein the error criterion is equal to the error between the measured time reflectogram and the simulated time reflectogram, weighted so as to assign a temporally decreasing weight to the peaks of the reflectograms.

13. The method for reconstructing the topology of a cable network as claimed in claim 1, comprising a step of displaying the reconstructed topology of the cable network on a display device.

14. The method for reconstructing the topology of a cable network as claimed in claim 1, comprising a preliminary step of injecting the signal into the cable network.

15. A computer program comprising instructions for executing the method for reconstructing the topology of a cable network as claimed in claim 1, when the program is executed by a processor.

16. A recording medium able to be read by a processor and on which there is recorded a program comprising instructions for executing the method for reconstructing the topology of a cable network as claimed in claim 1 when the program is executed by a processor.
